(19) United States
(12) Patent Application Publication
(10) Pub. No.: US 2009/0134433 A1
(43) Pub. Date: May 28, 2009

(54) Image sensor

(75) Inventor: Sang-Il Jung, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/291,650

(22) Filed: Nov. 12, 2008

(30) Foreign Application Priority Data
Nov. 15, 2007 (KR) 1020070116593

(51) Int. Cl. H01L 31/0232; H01L 29/66

(52) U.S. Cl. 257/239; 257/436; 257/E31.127; 257/E29.166

(57) ABSTRACT

An image sensor includes a substrate in which an active pixel region and an optical black region are defined, a plurality of active pixels in the active pixel region, each active pixel including a first charge-detection unit having a first conversion gain, and a plurality of black pixels in the optical black region, each black pixel including a second charge-detection unit having a second conversion gain.

### CROSS-REFERENCE TO RELATED APPLICATION

This application is based on and claims priority from Korean Patent Application No 10-2007-0116593, filed on Nov. 15, 2007, in the Korean Intellectual Property Office, the disclosure of which is incorporated herein in its entirety by reference.

### BACKGROUND OF THE INVENTION

1. Field of the Invention

Embodiments of the present specification relates to an image sensor, and more particularly to a MOS image sensor.

2. Description of the Prior Art

An image sensor converts an optical image into electrical signals. With continuing development of the computer and communications industries, there is an increasing demand for image sensors having improved performance for application in devices including digital cameras, camcorders, personal communication systems (PCSs), game machines, guard cameras, micro-cameras for medical use, robots, and the like.

A MOS image sensor has a simple drive system and adopts diverse scanning methods. In addition, its signal processing circuit can be integrated into a single chip to facilitate product miniaturization, and MOS device processing technology can lower the manufacturing cost of the sensor. Since the MOS image sensor has a very low power consumption, it can be easily applied to a product having a limited battery capacity. Accordingly, with the development of corresponding technology, the MOS image sensor now has a high resolution, and is now widely employed.

The MOS image sensor includes an active pixel region where a plurality of active pixels are formed and an optical black region where a plurality of black pixels are formed. In a photoelectric conversion element in the active pixel, charge is produced not only by photoelectric conversion, but also by heat. In contrast, in a photoelectric conversion element in the black pixel, light incident on the photoelectric conversion element is intercepted by a black matrix, and thus charge is not produced by photoelectric conversion but, rather, solely by heat.

In order to accurately obtain only the charge produced by the photoelectric conversion, the amount of charge produced by heat must be subtracted from the total amount of measured charge. Accordingly, an ADLC (Auto Dark Level Compensation) circuit receives voltage signals output from the active pixel region and the optical black region, performs a subtraction of the received voltage signals, and outputs a digital image signal that accurately corresponds to the amount of charge produced by the photoelectric conversion.

However, in a case where the amount of charge produced by heat generated from the active pixels is smaller than that produced by heat generated from the black pixels, the amount of charge produced by the photoelectric conversion during the signal subtraction by the ADCL circuit is reduced. This scenario, in turn, can cause image defects to occur.

In order to prevent the above-described image defects, research has been conducted to reduce or remove photoelectric-conversion units of the black pixels. In this case, however, it is difficult to accurately calculate the amount of charge produced by the photoelectric conversion and to prevent the image defect occurring due to temperature increase.

### SUMMARY OF THE INVENTION

Accordingly, embodiments of the present invention address the above-mentioned problems occurring in the conventional approaches, and an object of the present invention is to provide an image sensor having a reduced image defect.

Additional advantages, objects, and features of the invention will be set forth in part in the description which follows and in part will become apparent to those having ordinary skill in the art upon examination of the following or may be learned from practice of the invention.

In one aspect, an image sensor comprises: a substrate in which an active pixel region and an optical black region are defined; a plurality of active pixels provided in the active pixel region, each active pixel including a first charge-detection unit having a first conversion gain; and a plurality of black pixels provided in the optical black region, each black pixel including a second charge-detection unit having a second conversion gain that is different than the first conversion gain.

In one embodiment, the first conversion gain is greater than the second conversion gain.

In another embodiment, the first charge-detection unit has a first junction capacitance, the second charge-detection unit has a second junction capacitance; and the second junction capacitance is greater than the first junction capacitance.

In another embodiment, the substrate is a first conduction type substrate having a first doping density, and the first and second charge-detection units are of a second conduction type; wherein the image sensor further comprises a first well of the first conduction type that is in the active pixel region and has a second doping density that is greater than a first doping density, and a second well of the first conduction type that is in the optical black region and has the second doping density; and wherein the first charge-detection unit is in the substrate at a location outside the first well, and wherein the second charge-detection unit is in the second well.

In another embodiment, the image sensor further comprises a first well of a first conduction type that is in the active pixel region, and a second well of the first conduction type that is in the optical black region; wherein the first and second charge-detection units are of a second conduction type; and wherein the first charge-detection unit is in the first well, the second charge-detection unit is in the second well, and a doping density of the second well is greater than a doping density of the first well.

In another embodiment, the first and second charge-detection units are of a second conduction type; and the first charge-detection unit has a first doping density, the second charge-detection unit has a second doping density, and the second doping density is greater than the first doping density.

In another embodiment, the active pixel further comprises a first charge-transfer unit that transfers the charge to the first charge-detection unit; wherein the black pixel further comprises a second charge-transfer unit that transfers dark charge to the second charge-detection unit; and wherein a capacitance between the second charge-detection unit and the second charge-transfer unit is greater than a capacitance between the first charge-detection unit and the first charge-transfer unit.

In another embodiment, the first and second charge-transfer units overlap the first and second charge-detection units, respectively, and an area of overlap between the second charge-transfer unit and the second charge-detection unit is greater than an area of overlap between the first charge-transfer unit and the first charge-detection unit.

In another embodiment, the active pixel further comprises a first reset unit that resets the first charge-detection unit; wherein the black pixel further comprises a second reset unit that resets the second charge-detection unit; and wherein a capacitance between the second charge-detection unit and the second reset unit is greater than a capacitance between the first charge-detection unit and the first reset unit.

In another embodiment, the first and second charge-transfer units overlap the first and second reset units, respectively, wherein an area of overlap between the second charge-detection unit and the second reset unit is greater than an area of overlap between the first charge-detection unit and the first reset unit.

In another embodiment, a layout configuration of the active pixel and a layout configuration of the black pixel are equal to each other.

In another aspect, an image sensor comprises: a substrate of a first conduction type in which an optical black region is defined; a well of the first conduction type in the optical black region; and a charge-detection unit on the well of the first conduction type.

In one embodiment, the image sensor further comprises a plurality of black pixels in the optical black region; wherein each of the black pixels comprises a photoelectric-conversion unit producing dark charge due to an interception of incident light, a charge-transfer unit transferring charge to the charge-detection unit, a reset unit resetting the charge-detection unit, an amplifying unit coupled to the charge-detection unit, and a selection unit coupled to the amplifying unit.

In another embodiment, the photoelectric-conversion unit is not present in the well of the first conduction type.

In another embodiment, the reset unit is in the well of the first conduction type.

In another embodiment, the amplifying unit and the selection unit are not present in the well of the first conduction type.

In another aspect, an image sensor comprises: a P-type substrate with a first doping density in which an active pixel region and an optical black region are defined; a first P-type well with a second doping density that is in the active pixel region; a second P-type well with the second doping density that is in the optical black region; and a plurality of active pixels in the active pixel regions and a plurality of black pixels in the optical black region; wherein the active pixel includes a first photoelectric-conversion unit that produces charge in response to an incident light, a first N-type charge-detection unit receiving the charge from the first photoelectric-conversion unit, a first charge-transfer unit transferring the charge to the first charge-detection unit, a first reset unit resetting the first charge-detection unit, a first amplifying unit coupled to the first charge-detection unit, and a first selection unit coupled to the first amplifying unit; wherein the black pixel includes a second photoelectric-conversion unit that produces dark charge due to an interception of the incident light, a second N-type charge-detection unit receiving the charge from the second photoelectric-conversion unit, a second charge-transfer unit transferring the charge to the second charge-detection unit, a second reset unit resetting the second charge-detection unit, a second amplifying unit coupled to the second charge-detection unit, and a second selection unit coupled to the second amplifying unit; wherein a layout configuration of the first photoelectric-conversion unit is equal to a layout configuration of the second photoelectric-conversion unit; and wherein the first charge-detection unit is not present in the first well, and wherein the second charge-detection unit is in the second well.

In one embodiment, the second doping density is greater than the first doping density.

In another embodiment, the first and second photoelectric-conversion units, the first and second charge-transfer units, the first and second amplifying units, and the first and second selection unit are not present in the first and second wells, respectively.

In another embodiment, the first and second reset units are within the first and second wells respectively.

### BRIEF DESCRIPTION OF THE DRAWINGS

The above and other objects, features and advantages of the embodiments of the present invention will be apparent from the following detailed description taken in conjunction with the accompanying drawings, in which:

FIG. 1 is a view explaining a pixel array of an image sensor according to embodiments of the present invention;

FIG. 2 is a view illustrating in detail a part of the pixel array of FIG. 1;

FIGS. 3 and 4A to 4C are views explaining a process in which an active pixel and a black pixel of an image sensor output a first voltage signal and a second voltage signal, respectively, according to embodiments of the present invention;

FIGS. 5A and 5B are graphs explaining the effects of an image sensor according to embodiments of the present invention;

FIG. 6 is a sectional view explaining factors that affect the conversion gain according to embodiments of the present invention;

FIG. 7 is a layout diagram explaining an image sensor according to a first embodiment of the present invention;

FIG. 8 is a sectional view taken along lines A-A′ and B-B′ of FIG. 7;

FIG. 9 is a sectional view explaining an image sensor according to a second embodiment of the present invention;

FIG. 10 is a sectional view explaining an image sensor according to a third embodiment of the present invention;

FIG. 11 is a sectional view explaining an image sensor according to a fourth embodiment of the present invention; and

FIG. 12 is a schematic block diagram illustrating the construction of a processor-based system that includes an image sensor according to embodiments of the present invention.

### DETAILED DESCRIPTION OF PREFERRED EMBODIMENTS

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

It will be understood that, although the terms first, second, etc. are used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

In the embodiments of the present invention, an image sensor that is formed through a CMOS process will be described as an example of an image sensor. However, the image sensor according to the present invention may include any image sensor formed through only an NMOS or PMOS process or through a CMOS process using both the NMOS and PMOS processes.

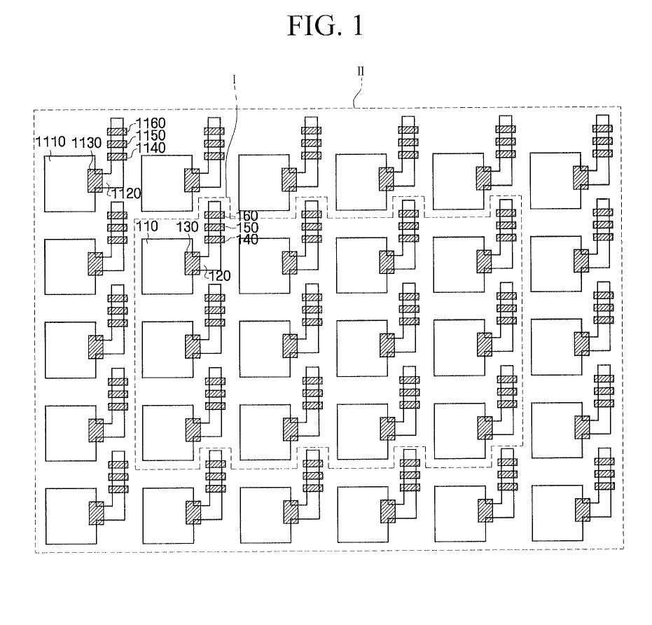

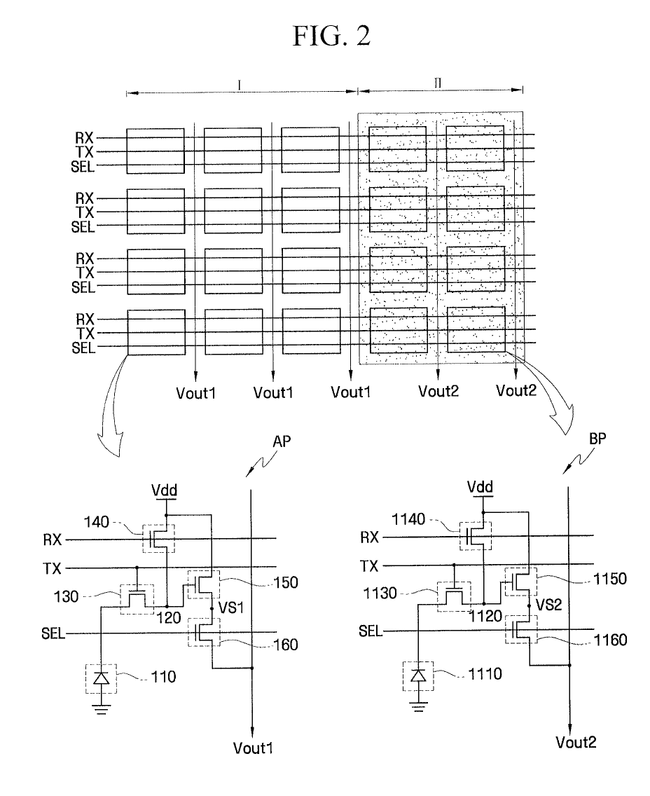

FIG. 1 is a view depicting a pixel array of an image sensor according to embodiments of the present invention, and FIG. 2 is a view illustrating in detail a portion of the pixel array of FIG. 1. In FIG. 2, it is exemplified that four transistors constitute a unit pixel. However, embodiments of the present invention are not limited thereto. For example, the unit pixel may be composed of five transistors, or another amount of transistors.

Referring to FIGS. 1 and 2, a pixel array of an image sensor according to embodiments of the present invention includes an active pixel region I and an optical black region II. In FIG. 1, it is exemplified that the optical black region II surrounds the active pixel region I; however, embodiments of the invention are not limited thereto. For example, the optical black region II may be arranged at only one side, or two sides, of the active pixel region I.

In the active pixel region I, a plurality of active pixels AP are formed. Each active pixel AP outputs a first voltage signal Vout1 in response to incident light. Such an active pixel AP includes a first photoelectric-conversion unit 110, a first charge-transfer unit 130, a first amplifying unit 150, a first reset unit 140, and a first selection unit 160.

The first photoelectric-conversion unit 110 produces and accumulates charge through photoelectric conversion in response to an incident light. The first photoelectric-conversion unit 110 may include, for example, a photo diode, a photo transistor, a photo gate, a pinned photo diode, or a combination thereof. In the drawing, a photo diode is illustrated.

The first charge-transfer unit 130 transfers charge accumulated in the first photoelectric-conversion unit 110 to the first charge-detection unit 120 in response to a transfer signal TX.

The first charge-detection unit 120 is in an electrically floating state, and thus is also referred to as a floating diffusion region. The first charge-detection unit 120 has a parasitic capacitance, and the charge is accumulatively stored in the first charge-detection unit 120. The first charge-detection unit 120 receives the charged produced by the first photoelectric-conversion unit 110.

The first reset unit 140 periodically resets the first charge-detection unit 120. The first reset unit 140 is coupled between a voltage node to which a specified voltage, e.g., a power supply voltage VDD, is applied and the first charge-detection unit 120, and is driven by a reset signal RX input to its gate. If the first reset unit 140 is turned on by the reset signal RX, the power supply voltage VDD is transferred to the first charge-detection unit 120 to reset the first charge-detection unit 120.

The first amplifying unit 150 outputs the voltage of the first charge-detection unit to an output line through the first selection unit 160. The first amplifying unit 150 serves as a source follower buffer amplifier in association with a constant current source (not illustrated). Specifically, since the first amplifying unit 150 is coupled to a current source (not illustrated) and current of a specified level flows through the first amplifying unit, the source voltage VS1 of the first amplifying unit 150 is varied in proportion to the gate voltage (i.e., the voltage of the first charge-detection unit 120). The source voltage varied as above is output to the output line.

The first selection unit 160 serves to select the active pixel AP. The first selection unit 160 is coupled to the first amplifying unit 150, and is driven by a selection signal SEL input to its gate.

In the optical black region II, a plurality of black pixels BP are provided. Each black pixel BP outputs a second voltage signal Vout2 that corresponds to the light quantity of the charge produced by heat. This black pixel BP includes a second photoelectric-conversion unit 1110, a second charge-transfer unit 1130, a second amplifying unit 1150, a second reset unit 1140, and a second selection unit 1160. Since the black pixel BP has substantially the same construction as the active pixel AP as described above except that the incident light is intercepted by a black matrix, the detailed description of the corresponding constituent elements will be omitted.

The reason why the optical black region II is necessary will now be described in detail.

In the first photoelectric-conversion unit 110 of the active pixel AP, charge is produced by not only photoelectric conversion, but also by heat. In contrast, in the second photoelectric-conversion unit 1110 of the black pixel BP, incident light is intercepted by a black matrix, and thus, charge is not produced by the photoelectric conversion, but instead is produced by the heat. The charge produced by the heat is referred to as “dark charge”. In order to accurately obtain the charge produced by the photoelectric conversion, the amount of dark charge produced by heat must be subtracted from the total amount of charge measured. An ADLC (Auto Dark Level Compensation) circuit receives first and second voltage signals Vout1 and Vout2 output from the active pixel region I and the optical black region II, performs a subtraction of the first and second voltages (i.e., Vout1-Vout2), and outputs a digital image signal that accurately corresponds to the amount of charge produced by photoelectric conversion.

That is, the optical black region II is provided to remove an error that can occur due to generation of dark charge due to heat, as described above, or to remove the influence that is exerted by offset commonly existing in the first photoelectric-conversion unit 110 of the active pixel region I and in the second photoelectric-conversion unit 1110 of the optical black region II.

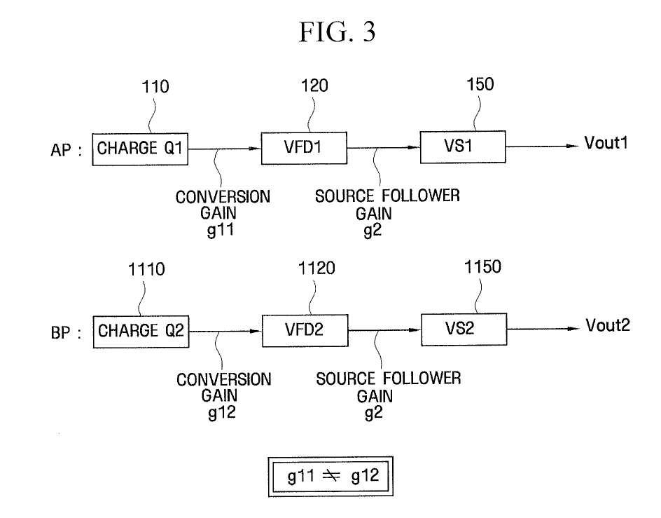

FIGS. 3 and 4A to 4C are views explaining a process by which an active pixel and a black pixel of an image sensor output a first voltage signal and a second voltage signal, respectively, according to embodiments of the present invention.

Prior to the explanation of the process by which the active pixel AP and the black pixel BP output the first voltage signal Vout1 and the second voltage signal Vout2, respectively, a conversion gain and a source follower gain will be described in detail.

The conversion gain G1 can be defined as in Equation (1) below. Referring to Equation (1), the conversion gain G1 is in proportion to a value obtained by dividing an amount of voltage change Δ VFD of the charge-detection unit by the charge Q. That is, the conversion gain G1 has a value indicating how much one charge Q changes the voltage VFD of the charge-detection unit. Also, the conversion gain G1 is in inverse proportion to the capacitance C of the charge-detection unit. Accordingly, as the capacitance C of the charge-detection unit is increased, the conversion gain G1 is decreased.

G1∝ΔVFD/Q=1/C (1)

The source follower gain G2 can be defined as in Equation (2). The source follower gain G2 has a value indicating how large is the amount of source voltage change Δ VS of the amplifying unit that is changed according to the amount of voltage change Δ VFD of the charge-detection unit. That is, if the source follower gain G2 is great, the amount of voltage change ΔVFD of the charge-detection unit is well reflected in the source voltage VS.

G2∝ΔVS/ΔVFD (2)

Accordingly, the values of the first and second voltage signals Vout1 and Vout2 may be changed depending on the conversion gain G1 and the source follower gain G2.

The values of the conversion gain G1 and the source follower gain G2 of the system can be changed according to the layout configuration and various process conditions.

Here, referring to FIG. 3, the charge Q1 accumulated in the first photoelectric-conversion unit 110 of the active pixel AP is transferred to the first charge-detection unit 120, and, at this time, the voltage VFD1 of the first charge-detection unit 120 is changed according to the first conversion gain g11. Then, the source voltage VS1 of the first amplifying unit 150 is changed according to the voltage VFD1 of the first charge-detection unit 120, and the degree of change is determined by the source follower gain g2. That is, the value of the first voltage signal Vout1 output from the active pixel AP can vary in response to the first conversion gain g11 and the source follower gain g2.

In addition, the charge Q2 accumulated in the second photoelectric-conversion unit 1110 of the black pixel BP is transferred to the second charge-detection unit 1120, and, at this time, the voltage VFD2 of the second charge-detection unit 1120 is changed according to the second conversion gain g12. Then, the source voltage VS2 of the second amplifying unit 1150 is changed according to the voltage VFD2 of the second charge-detection unit 1120, and the degree of change is determined by the source follower gain g2. That is, the value of the second voltage signal Vout2 output from the black pixel BP can vary in response to the second conversion gain g12 and the source follower gain g2.

However, in the image sensor according to the embodiments of the present invention, the first conversion gain g11 of the active pixel AP and the second conversion gain g12 of the black pixel BP can be different (i.e., g11≠g12). The reason will now be described with reference to FIGS. 3 and 4A to 4C. FIG. 4A shows a case where the second conversion gain g12 is larger than the first conversion gain g11, FIG. 4B shows a case where the second conversion gain g12 is equal to the first conversion gain g11, and FIG. 4C shows a case where the second conversion gain g12 is smaller than the first conversion gain g11.

First, referring to FIGS. 3 and 4A, the first voltage signal Vout1 of the active pixel AP may be divided into a dark level (D/L) 210 and a signal level (S/L) 220. Here, the dark level 210 indicates a voltage that corresponds to the charge produced by heat and other offsets, and the signal level 220 indicates a voltage that corresponds to the charge produced by photoelectric conversion.

The second voltage signal Vout2 of the black pixel BP includes only the dark level 212.

However, since manufacturing environments or other variables may differ, the dark level 210 of the first voltage signal Vout1 and the dark level 212 of the second voltage signal Vout2 have their own dispersions. Accordingly, the dark level 210 of the first voltage signal Vout1 may differ from the dark level 212 of the second voltage signal Vout2. In particular, as illustrated in FIG. 4A, the dark level 212 of the second voltage signal Vout2 may be higher than the dark level 210 of the first voltage signal Vout1. In this case, in order to calculate the voltage corresponding to the charge produced by the photoelectric conversion, i.e., the signal level 220, the difference (Vout1−Vout2) between the first voltage signal Vout1 and the second voltage signal Vout2 is obtained, which becomes a signal level 222 that is lower than the signal level 220 of the first voltage signal Vout1. Consequently, through the process of obtaining the difference (Vout1−Vout2), an image defect caused by the decreased signal level 222 may occur.

In order to prevent such an image defect, in the image sensor according to the embodiments of the present invention, the first conversion gain g11 of the active pixel AP and the second conversion gain g12 of the black pixel BP are adjusted in a different manner. For example, the second conversion gain g12 of the black pixel BP may be set to be a gain level that is smaller than the gain level of the first conversion gain g11 of the active pixel AP.

As described above, the value of the second voltage signal Vout2 output from the black pixel BP is changed depending on the second conversion gain g12. Accordingly, by making the second conversion gain g12 smaller than the first conversion gain g11, the dark level of the second voltage signal Vout2 is decreased.

Referring to FIG. 4B, the dark level 214 of the second voltage signal Vout2 is substantially equal to the dark level 210 of the first voltage signal Vout1. That is, as the second conversion gain g12 is decreased, the dark level 214 of the second voltage signal Vout2 becomes lower than the dark level 212 of the second voltage signal Vout2 as illustrated in FIG. 4A. Accordingly, even if the difference (Vout1−Vout2) is obtained, the signal level 224 is not decreased.

Referring to FIG. 4C, the dark level 216 of the second voltage signal Vout2 is lower than the dark level 210 of the first voltage signal Vout1. That is, as the second conversion gain g12 is decreased, the dark level 216 of the second voltage signal Vout2 becomes lower than the dark level 212 of the second voltage signal Vout2 as illustrated in FIG. 4A. Accordingly, even if the difference (Vout1−Vout2) is obtained, the signal level 226 is not decreased.

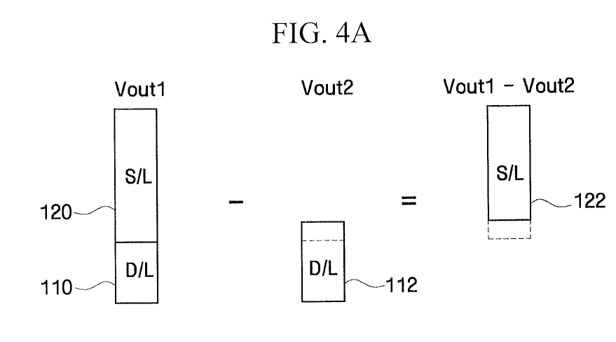

FIGS. 5A and 5B are graphs explaining the effects of an image sensor according to embodiments of the present invention. FIGS. 5A and 5B show the difference between the first voltage signal Vout1 and the second voltage signal Vout2 in a state where almost no light is incident.

FIG. 5A is a view explaining the operation characteristics of an image sensor designed so that the second conversion gain g12 is equal to the first conversion gain g11. However, even though the image sensor is designed as described above, dispersions may exist between a plurality of active pixels AP and a plurality of black pixels BP. Accordingly, the dark level of the second voltage signal Vout2 may be greater than the dark level of the first voltage signal Vout1, and the difference (Vout1−Vout2) may be lower than 0 mV.

FIG. 5B is a view explaining the operation characteristics of an image sensor designed so that the second conversion gain g12 is smaller than the first conversion gain g11. In this case, the dark level of the second voltage signal Vout2 is equal to or less than the dark level of the first voltage signal Vout1 even though dispersions exist between the plurality of active pixels AP and the plurality of black pixels BP, and thus the difference (Vout1−Vout2) is greater than 0 mV. That is, by designing the image sensor so that the second conversion gain g12 is smaller than the first conversion gain g11, the difference (Vout1−Vout2) is always greater than 0 mV in order to prevent the image defect.

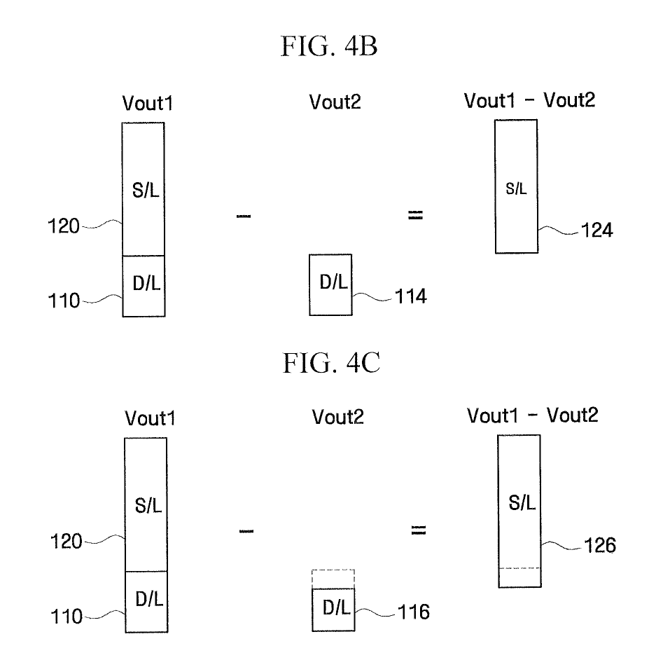

Hereinafter, with reference to FIG. 6, factors for making the second conversion gain g12 smaller than the first conversion gain g11 will be presented. FIG. 6 is a sectional view explaining factors that affect the conversion gain according to embodiments of the present invention.

Referring to FIG. 6 and Equation (1), the conversion gain G1 is inversely proportional to the capacitance of the charge-detection units 120 and 1120, and thus in order to make the difference (Vout1−Vout2) between the first voltage signal Vout1 and the second voltage signal Vout2 greater than 0 mV, the capacitance C1 of the first charge-detection unit 120 should be less than the capacitance C2 of the second charge-detection unit 1120.

Here, the capacitance C1 of the first charge-detection unit 120 of the active pixel AP can be expressed by Equation (3). Referring to Equation (3), the capacitance C1 of the first charge-detection unit 120 can be expressed as the sum of a first junction capacitance C11, a capacitance C12 formed between the first charge-detection unit 120 and the first charge-transfer unit 130, and a capacitance C13 formed between the first charge-detection unit 120 and the first reset unit 140, and is dependent upon these values.

C1=C11+C12+C13 (3)

In the same manner, the capacitance C2 of the second charge-detection unit 1120 of the black pixel BP can be expressed by Equation (4). Referring to Equation (4), the capacitance C2 of the second charge-detection unit 1120 can be expressed as the sum of a second junction capacitance C21, a capacitance C22 formed between the second charge-detection unit 1120 and the second charge-transfer unit 1130, and a capacitance C23 formed between the second charge-detection unit 1120 and the second reset unit 1140, and is dependent upon these values. Accordingly, by increasing at least one of the second junction capacitance C21, the capacitance C22 formed between the second charge-detection unit 1120 and the second charge-transfer unit 1130, and the capacitance C23 formed between the second charge-detection unit 1120 and the second reset unit 1140, and making the remaining values constant, the capacitance C2 of the second charge-detection unit 1120 can be increased.

C2=C21+C22+C23 (4)

In order to prevent the image defect by making the second conversion gain g12 of the black pixel BP less than the first conversion gain g11 of the active pixel AP, the capacitance C2 of the second charge-detection unit 1120 may be set to be greater than the capacitance C1 of the first charge-detection unit 120.

Hereinafter, with reference to the accompanying drawings, exemplary embodiments of the present invention for making the capacitance C1 of the first charge-detection unit 120 less will be described.

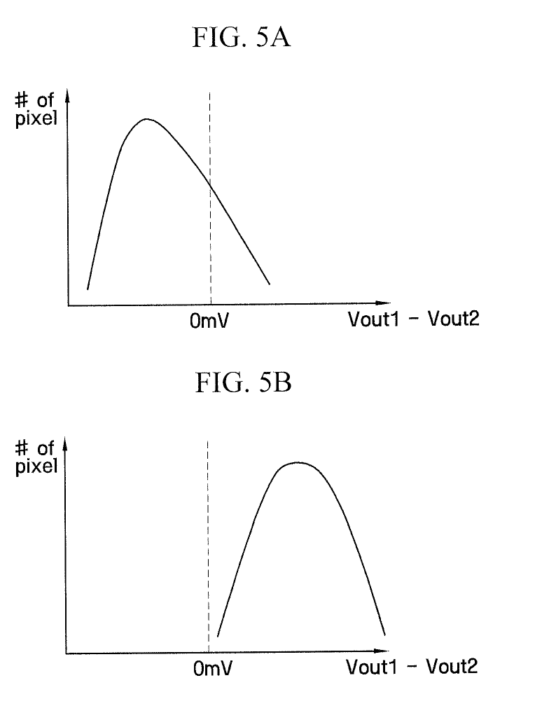

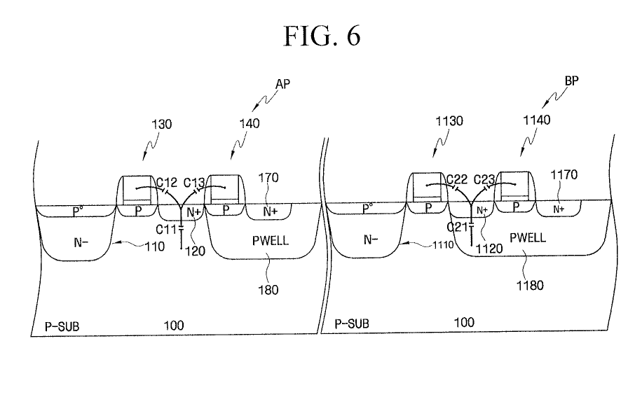

First, with reference to FIGS. 7 and 8, the image sensor according to the first embodiment of the present invention will be described in detail.

FIG. 7 is a layout diagram explaining an image sensor according to a first embodiment of the present invention, and FIG. 8 is a sectional view taken along lines A-A′ and B-B′ of FIG. 7. The layout as illustrated in FIG. 7 is exemplary, and thus the present invention is not limited thereto.

Referring to FIGS. 7 and 8, the active pixel region and the optical black region are defined on a first conduction type (e.g., P-type) substrate 100 having a first doping density (e.g., density of P−) by forming an element-separation region such as STI (Shallow Trench Isolation) in the first conduction type (e.g., P-type) substrate 100. In FIG. 7, for convenience of explanation, one active pixel AP formed in an active pixel region and one black pixel BP formed in an optical black region are illustrated.

A first well 180 of a first conduction type formed in the active pixel region is not formed on lower parts of the first photoelectric-conversion unit 110, the first charge-transfer region 130, the first charge-detection unit 120, the first amplifying unit 150, and the first selection unit 160. That is, the first photoelectric-conversion unit 110, the first charge-transfer region 130, the first charge-detection unit 120, the first amplifying unit 150, and the first selection unit 160 are formed on the substrate 100 (where the first well 180 does not exist). That is, only the first reset unit 140 and/or a first source/drain part 170 may be formed in the first well 180.

Since the first well 180 has a second doping density (e.g., a density of P) that is higher than a first doping density of the substrate 100, the first photoelectric-conversion unit 110, the first amplifying unit 150, and so forth, are not formed in the first well 180.

Specifically, if the first photoelectric-conversion unit 110 is formed in the first well 180, the area of a depletion region of the first photoelectric-conversion unit 110 formed in the first well 180 becomes smaller than the area of a depletion region of the first photoelectric-conversion unit 110 formed in the substrate 100. Since the efficiency of the photoelectric conversion becomes higher as the depletion region becomes larger, it is preferable to form the first photoelectric-conversion unit 110 in the substrate 110 that is not the first well 180.

Also, if the first amplifying unit 150 is formed in the first well 180, the source follower gain of the first amplifying unit 150 formed in the first well 180 is smaller than the source follower gain of the first amplifying unit 150 formed in the substrate 100. This is because the source follower gain is inversely proportional to a body-effect coefficient γ, and this body-effect coefficient γ is proportional to the doping density N_{B} of dopant. Since the active pixel AP should output the first voltage signal Vout1 that is proportional to the amount of charge accumulated in the first photoelectric-conversion unit 110, a larger source follower gain is preferable. Accordingly, it is preferable that the first amplifying unit 150 of the active pixel AP is formed in the substrate 100 that is not the first well 180.

By contrast, a second well 1180 of the first conduction type formed in the optical black region is not formed on lower parts of the second photoelectric-conversion unit 1110, the second charge-transfer region 1130, the second amplifying unit 1150, and the second selection unit 1160. That is, the second photoelectric-conversion unit 1110, the second charge-transfer region 1130, the second amplifying unit 1150, and the second selection unit 1160 are formed on the substrate 100 (where the second well 1180 does not exist). Also, the first reset unit 140 and a second source/drain part 1170 may be formed in the second well 1180.

As described above with reference to FIGS. 3 to 4C, the second conversion gain g12 of the black pixel BP is adjusted to be smaller than the first conversion gain g11 of the active pixel AP. That is, the capacitance C2 of the second charge-detection unit 1120 is adjusted to be greater than the capacitance C1 of the first charge-detection unit 120. For this, the second charge detection part 1120 of the second conduction type is formed in the second well 1180 having the second doping density. In this case, the first charge-detection unit 120 of the second conduction type is formed on the substrate 100 having the first doping density that is lower than the second doping density, but is not formed in the first well 180 having the second doping density.

That is, in the image sensor according to the present embodiment, the doping density (e.g., a density of P) of the circumference of the second charge-detection unit 1120, i.e., the density of the second well 1180 is higher than the doping density (density of P—) of the circumference of the first charge-detection unit 120, i.e., the density of the substrate 100. Accordingly, the depletion region between the second charge-detection unit 1120 and the second well 1180 that surrounds the second charge-detection unit 1120 becomes thinner than the depletion region between the first charge-detection unit 120 and the substrate 100 that surrounds the first charge-detection unit 120. Since the junction capacitance of the first and second charge-detection units 120 and 1120 (See C11 and C21 of FIG. 6) becomes larger as the depletion region is thinner, the second junction capacitance of the second charge-detection unit 1120 (See C21 of FIG. 6) becomes larger than the first junction capacitance of the first charge-detection unit 120 (See C11 of FIG. 6). Consequently, as described above with reference to FIGS. 3 to 4C, the second conversion gain g12 of the black pixel BP becomes smaller than the first conversion gain g11 of the active pixel AP to reduce the likelihood of the occurrence of image defect.

In contrast, as illustrated in FIG. 6, the layout configuration of the active pixel AP may be equal to the layout configuration of the black pixel BP. Specifically, the charge is thermally produced/accumulated on the surface of the first photoelectric-conversion unit 110, between the gate of the first charge-transfer unit 130 and the substrate 100, at STI boundaries, and so forth. Accordingly, in the event that the layout configuration of the active pixel AP and the layout configuration of the black pixel BP differ from each other, the dark level of the first voltage signal Vout1 output form the active pixel AP and the dark level of the second voltage signal Vout2 output from the black pixel BP become different from each other. Accordingly, in order to accurately obtain only the charge produced by the photoelectric conversion in the active pixel AP, it is preferable that the layout configuration of the active pixel AP and the layout configuration of the black pixel BP are equal to each other. In the present embodiment, the term “the layout configuration of the active pixel AP and the layout configuration of the black pixel BP are equal to each other” includes a case where only the first well 180 and the second well 1180 of the pixels AP, BP may be different from each other, but the other elements of the pixels AP, BP are equal to each other.

Hereinafter, with reference to FIG. 8, the operation of the respective elements according to the present embodiment will be described in more detail.

The first and second photoelectric-conversion units 110 and 1110 are formed in the substrate 100, and include first and second N-type photo diodes 112 and 1112, and first and second P⁰-type pinning layers 114 and 1114. The first and second photo diodes 112 and 1112 accumulate the charge produced corresponding to an incident light, and the first and second pinning layers 114 and 1114 serve to reduce the dark current by reducing EHP (Electron-Hole Pairs) thermally produced on an upper part of the substrate 100.

Floating diffusion (FD) regions are mainly used as the first and second charge-detection units 120 and 1120, and the first and second charge-detection units 120 and 1120 receive the charge accumulated in the first and second photoelectric-conversion units 110 and 1110 through the first and second charge-transfer units 130 and 1130.

The first charge-transfer unit 130 includes a first impurity region 132, a first gate insulation layer 134, a first gate electrode 136, and a first spacer 138.

The first impurity region 132 serves to prevent the dark current that can be generated as a false image sensed in a state where the first charge-transfer unit 130 is turned off.

The first gate insulation layer 134 may be made of SiO₂, SiON, SiN, Al₂O₃, Si₃N₄, GeₓO_{y}N_{z}, GeₓSi_{y}O_{z}, or a material with a high dielectric constant. Here, as the material with a high dielectric constant, a layer of HfO₂, ZrO₂, Al₂O₃, Ta₂O₅, hafnium silicate, zirconium silicate, or their combination may be formed through atomic layer deposition. Also, the gate insulation layer 134 may be formed by laminating plural layers made of two or more materials selected among the above-described layer materials.

The first gate electrode 136 may be composed of a conductive polysilicon layer, a metal layer such as W, Pt, or Al, a metal nitride layer such as TiN, a metal silicide layer obtained from refractory metal such as Co, Ni, Ti, Hf, and Pt, or a combination layer thereof.

The first spacer 138 is formed on both side walls of the first gate electrode 136, and may be made of silicon nitride layer SiN. The second charge-transfer unit 1130, the second amplifying unit 1150, the second reset unit 1140, and the second selection unit 1160 correspond to the first charge-transfer unit 130 except that they are formed in the black pixel BP region.

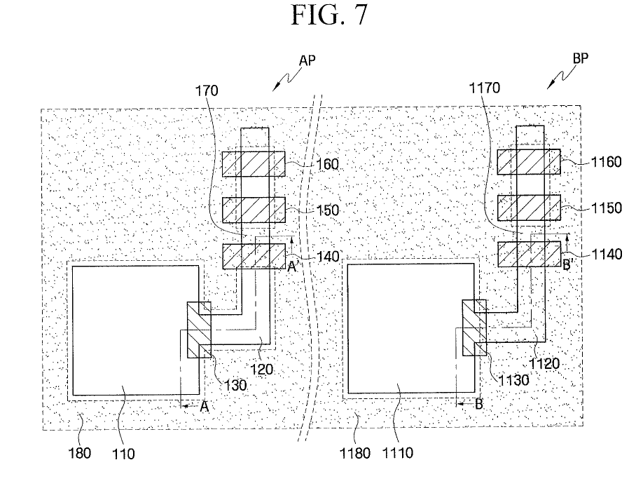

Hereinafter, with reference to FIG. 9, an image sensor according to the second embodiment of the present invention will be described. FIG. 9 is a sectional view explaining an image sensor according to the second embodiment of the present invention.

Referring to FIG. 9, according to the image sensor according to the second embodiment of the present invention, a second charge-detection unit 1121 of the black pixel region is formed in a second well 1181, and a first charge-detection unit 121 of the active pixel region is formed in the first well 180 of the first conduction type (e.g., P-type) as well.

The doping density (e.g., P+) of the second well 1181 of the first conduction type (e.g., P-type) may be higher than the doping density (e.g., P) of the first well 180. Accordingly, the depletion region between the second charge-detection unit 1121 of the second conduction type (e.g., N type) and the second well 1181 that surrounds the second charge-detection unit 1121 becomes thinner than the depletion region between the first charge-detection unit 121 of the second conduction type (e.g., N-type) and the first well 181 that surrounds the first charge-detection unit 121. Since the junction capacitance of the first and second charge-detection units 121 and 1121 (See C11 and C21 of FIG. 6) becomes larger as the depletion region thins, the second junction capacitance of the second charge-detection unit 1121 (See C21 of FIG. 6) becomes larger than the first junction capacitance of the first charge-detection unit 121 (See C11 of FIG. 6). Consequently, as described above with reference to FIGS. 3 to 4C, the second conversion gain g12 of the black pixel BP becomes less than the first conversion gain g11 of the active pixel AP to reduce the likelihood of the occurrence of image defects.

In the present embodiment, the layout configuration of the active pixel AP is completely equal to the layout configuration of the black pixel BP; however, the doping densities of the first well 181 and the second well 1181 differ from each other.

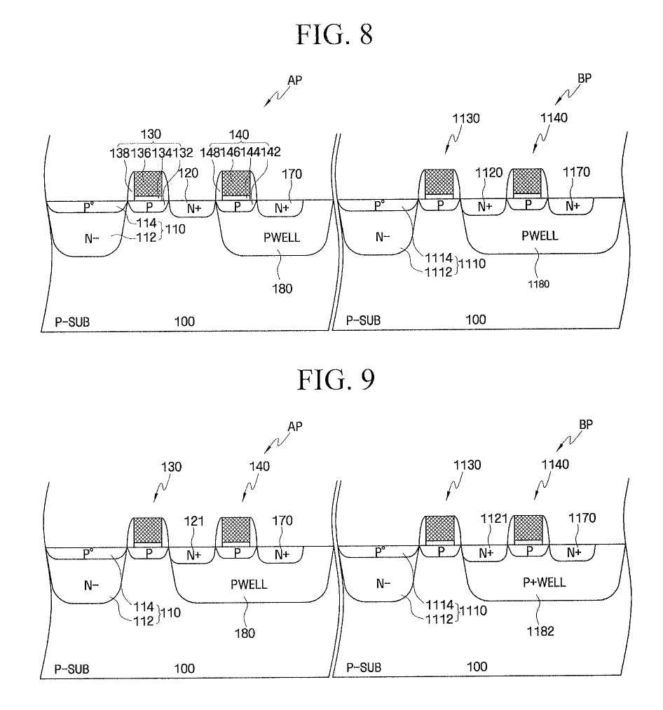

Hereinafter, with reference to FIG. 10, an image sensor according to a third embodiment of the present invention will be described. FIG. 10 is a sectional view explaining an image sensor according to the third embodiment of the present invention.

Referring to FIG. 10, according to the image sensor according to the third embodiment of the present invention, a second charge-detection unit 1122 is not formed in a second well 11821, but has a density different from that of the first charge-detection unit 120. The first and second charge-detection units 120 and 1121 are all of the second conduction type (e.g., N-type).

The first charge-detection unit 120 has the first doping density (e.g., density of N+), and the second charge-detection unit 1122 has the second doping density (e.g., density N++) that is higher than the first doping density. Accordingly, the depletion region between the second charge-detection unit 1122 having the second doping density (e.g., density of N++) and the first conduction type (e.g., P-type) substrate 100 having the density of P−, which surrounds the second charge-detection unit 1122, becomes thinner than the depletion region between the first charge-detection unit 120 having the first doping density (e.g., density of N+) and the first conduction type (e.g., P-type) substrate 100 having the density of P−, which surrounds the first charge-detection unit 120. Since the junction capacitance of the first and second charge-detection units 120 and 1122 (See C11 and C21 of FIG. 6) becomes larger as the depletion region thins, the second junction capacitance of the second charge-detection unit 1122 (See C21 of FIG. 6) becomes larger than the first junction capacitance of the first charge-detection unit 121 (See C11 of FIG. 6). Consequently, as described above with reference to FIGS. 3 to 4C, the second conversion gain g12 of the black pixel BP becomes smaller than the first conversion gain g11 of the active pixel AP to reduce the likelihood of the occurrence of image defects.

In the present embodiment, the layout configuration of the active pixel AP is equal to that of the layout configuration of the black pixel BP; however, the doping densities of the first charge-detection unit 120 and the second charge-detection unit 1122 differ from each other.

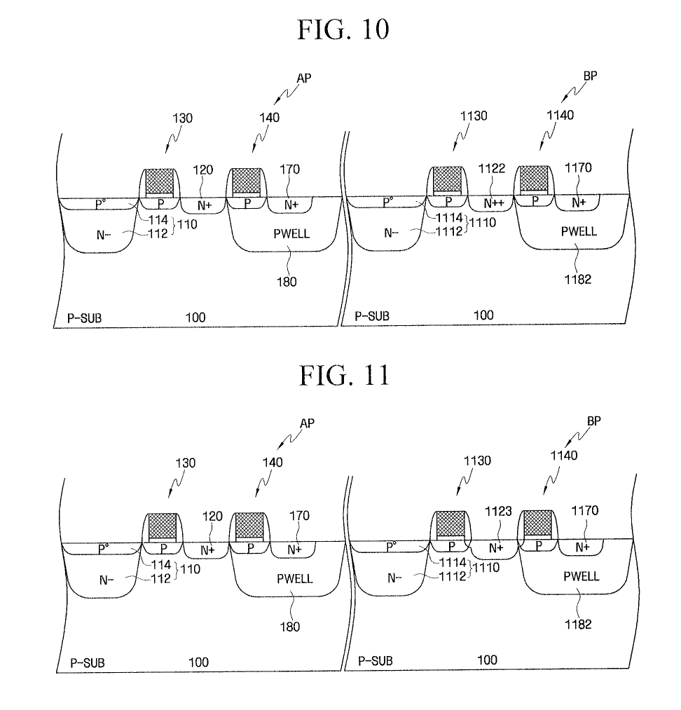

Hereinafter, with reference to FIG. 11, an image sensor according to a fourth embodiment of the present invention will be described. FIG. 11 is a sectional view explaining an image sensor according to the fourth embodiment of the present invention.

According to the image sensor according to the fourth embodiment of the present invention, by making the capacitance (See C22 of FIG. 6) between the second charge-detection unit 1123 and the second charge-transfer unit 1130 larger than the capacitance (See C12 of FIG. 6) between the first charge-detection unit 120 and the first charge-transfer unit 130, or by making the capacitance (See C23 of FIG. 6) between the second charge-detection unit 1123 and the second reset unit 1140 larger than the capacitance (See C13 of FIG. 6) between the first charge-detection unit 120 and the first reset unit 140, the likelihood of the occurrence of image defects can be reduced.

Referring to FIG. 11, according to the image sensor according to the fourth embodiment of the present invention, the densities of the first charge-detection unit 120 and the second charge-detection unit 1123 and/or the areas of the first well 180 and the second well 1182 are equal to each other, however, the amount of area of overlap between the first charge-detection unit 120 and the first charge-transfer unit 130 or the first reset unit 140 is different from the amount of area of overlap between the second charge-detection unit 1123 and the second charge-transfer unit 1130 or the second reset unit 1140. The overlapping area can be widened by performing implant of impurities having a sloped profile relative to the second charge-transfer unit 1130 or the second reset unit 1140 rather than performing the implant in a vertical direction.

For example, the overlapping area between the second charge-detection unit 1123 having the first density (e.g., N+) and the second charge-transfer unit 1130 can be set to be larger than the overlapping area between the first charge-detection unit 120 having the same density and the first charge-transfer unit 130. Accordingly, the capacitance between the second charge-detection unit 1123 and the second charge-transfer unit 1130 (See C22 of FIG. 6) can be set to be larger than the capacitance between the first charge-detection unit 120 and the first charge-transfer unit 130 (See C12 of FIG. 6), so that the likelihood of the occurrence of image defects can be reduced.

In addition, the overlapping area between the second charge-detection unit 1123 having the first density (e.g., N+) and the second reset unit 1140 can be set to be larger than the overlapping area between the first charge-detection unit 120 having the same density and the first reset unit 140. Accordingly, the capacitance between the second charge-detection unit 1123 and the second reset unit 1140 (See C23 of FIG. 6) can be set to be larger than the capacitance between the first charge-detection unit 120 and the first reset unit 140 (See C13 of FIG. 6), so that the likelihood of the occurrence of image defects can be reduced.

The overlap areas of the black pixel BP can be set in combination. That is, both the overlapping area between the second charge-detection unit 1123 and the second charge-transfer unit 1130, and the overlapping area between the second charge-detection unit 1123 and the second reset unit 1140 can be set to be larger than those corresponding overlapping areas of the active pixel AP, respectively.

In addition to those described above, all embodiments in which the capacitance of the black pixel BP (See C2 of FIG. 6) is made to be larger than the capacitance of the active pixel AP (See C1 of FIG. 6) are within the scope of the present invention.

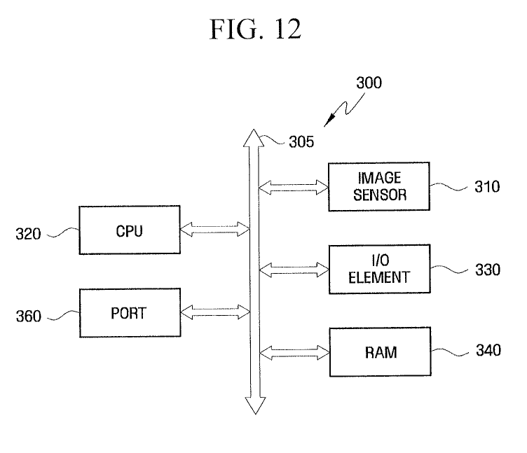

FIG. 12 is a schematic block diagram illustrating the construction of a processor-based system that includes an image sensor according to embodiments of the present invention.

Referring to FIG. 12, a processor-based system 300 is a system that processes an image output from a CMOS image sensor 310. The system 300 may be a computer system, a camera system, a scanner, a mechanized watch system, a navigation system, a video phone, a monitoring system, an auto focus system, a tracking system, an operation supervisory system, an image-stabilizing system, and so forth, but is not limited thereto.

The processor-based system 300, such as a computer system, includes a CPU 320 such as a microprocessor that can communicate with an input/output (I/O) element 330 through a bus 305. The CMOS image sensor 310 can communicate with a system through a bus 305 or other communication links. Also, the processor-based system 300 may further include a RAM 340 and/or port 360 which communicate with the CPU 320 through the bus 305. The port 360 is a port that couples a video card, a sound card, a memory card, a USB element, and so forth, or that communicates with other systems. The CMOS image sensor 310 can be integrated with a CPU, a DSP (Digital Signal Processor), or a microprocessor. Also, the CMOS image sensor may be integrated with a memory. Depending on the application, the CMOS image sensor may be integrated into a separate chip together with a processor.

While embodiments of the invention have been particularly shown and described with references to preferred embodiments thereof, it will be understood by those skilled in the art that various changes in form and details may be made herein without departing from the spirit and scope of the invention as defined by the appended claims.

What is claimed is:

1. An image sensor comprising:
a substrate in which an active pixel region and an optical black region are defined;
a plurality of active pixels provided in the active pixel region, each active pixel including a first charge-detection unit having a first conversion gain; and
a plurality of black pixels provided in the optical black region, each black pixel including a second charge-detection unit having a second conversion gain that is different than the first conversion gain.

2. The image sensor of claim 1, wherein the first conversion gain is greater than the second conversion gain.

3. The image sensor of claim 2, wherein the first charge-detection unit has a first junction capacitance, and wherein the second charge-detection unit has a second junction capacitance; and
wherein the second junction capacitance is greater than the first junction capacitance.

4. The image sensor of claim 3, wherein the substrate is a first conduction type substrate having a first doping density, and the first and second charge-detection units are of a second conduction type;
wherein the image sensor further comprises a first well of the first conduction type that is in the active pixel region and has a second doping density that is greater than a first doping density, and a second well of the first conduction type that is in the optical black region and has the second doping density; and
wherein the first charge-detection unit is in the substrate at a location outside the first well, and wherein the second charge-detection unit is in the second well.

5. The image sensor of claim 3, further comprising a first well of a first conduction type that is in the active pixel region, and a second well of the first conduction type that is in the optical black region;
wherein the first and second charge-detection units are of a second conduction type; and
wherein the first charge-detection unit is in the first well, the second charge-detection unit is in the second well, and a doping density of the second well is greater than a doping density of the first well.

6. The image sensor of claim 3, wherein the first and second charge-detection units are of a second conduction type; and
wherein the first charge-detection unit has a first doping density, the second charge-detection unit has a second doping density, and the second doping density is greater than the first doping density.

7. The image sensor of claim 2, wherein the active pixel further comprises a first charge-transfer unit that transfers the charge to the first charge-detection unit;
wherein the black pixel further comprises a second charge-transfer unit that transfers dark charge to the second charge-detection unit; and
wherein a capacitance between the second charge-detection unit and the second charge-transfer unit is greater than a capacitance between the first charge-detection unit and the first charge-transfer unit.

8. The image sensor of claim 7, wherein the first and second charge-transfer units overlap the first and second charge-detection units, respectively, and wherein an area of overlap between the second charge-transfer unit and the second charge-detection unit is greater than an area of overlap between the first charge-transfer unit and the first charge-detection unit.

9. The image sensor of claim 2, wherein the active pixel further comprises a first reset unit that resets the first charge-detection unit;
wherein the black pixel further comprises a second reset unit that resets the second charge-detection unit; and
wherein a capacitance between the second charge-detection unit and the second reset unit is greater than a capacitance between the first charge-detection unit and the first reset unit.

10. The image sensor of claim 9, wherein the first and second charge-transfer units overlap the first and second reset units, respectively, and wherein an area of overlap between the second charge-detection unit and the second reset unit is greater than an area of overlap between the first charge-detection unit and the first reset unit.

11. The image sensor of claim 1, wherein a layout configuration of the active pixel and a layout configuration of the black pixel are equal to each other.

12. An image sensor comprising:
a substrate of a first conduction type in which an optical black region is defined;
a well of the first conduction type in the optical black region; and
a charge-detection unit on the well of the first conduction type.

13. The image sensor of claim 12, further comprising a plurality of black pixels in the optical black region;
wherein each of the black pixels comprises a photoelectric-conversion unit producing dark charge due to an interception of incident light, a charge-transfer unit transferring charge to the charge-detection unit, a reset unit resetting the charge-detection unit, an amplifying unit coupled to the charge-detection unit, and a selection unit coupled to the amplifying unit.

14. The image sensor of claim 13, wherein the photoelectric-conversion unit is not present in the well of the first conduction type.

15. The image sensor of claim 13, wherein the reset unit is in the well of the first conduction type.

16. The image sensor of claim 13, wherein the amplifying unit and the selection unit are not present in the well of the first conduction type.

17. An image sensor comprising:
a P-type substrate with a first doping density in which an active pixel region and an optical black region are defined;
a first P-type well with a second doping density that is in the active pixel region;
a second P-type well with the second doping density that is in the optical black region; and
a plurality of active pixels in the active pixel regions and a plurality of black pixels in the optical black region;
wherein the active pixel includes a first photoelectric-conversion unit that produces charge in response to an incident light, a first N-type charge-detection unit receiving the charge from the first photoelectric-conversion unit, a first charge-transfer unit transferring the charge to the first charge-detection unit, a first reset unit resetting the first charge-detection unit, a first amplifying unit coupled to the first charge-detection unit, and a first selection unit coupled to the first amplifying unit;
wherein the black pixel includes a second photoelectric-conversion unit that produces dark charge due to an interception of the incident light, a second N-type charge-detection unit receiving the charge from the second photoelectric-conversion unit, a second charge-transfer unit transferring the charge to the second charge-detection unit, a second reset unit resetting the second charge-detection unit, a second amplifying unit coupled to the second charge-detection unit, and a second selection unit coupled to the second amplifying unit;
wherein a layout configuration of the first photoelectric-conversion unit is equal to a layout configuration of the second photoelectric-conversion unit; and
wherein the first charge-detection unit is not present in the first well, and wherein the second charge-detection unit is in the second well.

18. The image sensor of claim 17, wherein the second doping density is greater than the first doping density.

19. The image sensor of claim 17, wherein the first and second photoelectric-conversion units, the first and second charge-transfer units, the first and second amplifying units, and the first and second selection unit are not present in the first and second wells, respectively.

20. The image sensor of claim 17, wherein the first and second reset unit are within the first and second wells respectively.
